(19) United States
(12) Patent Application Publication
(10) Pub. No.: US 2026/0075706 A1
(43) Pub. Date: Mar. 12, 2026

(54) WIRING SUBSTRATE

(71) Applicant: IBIDEN CO., LTD., Gifu (JP)

(72) Inventor: Masatoshi KUNIEDA, Gifu (JP)

(73) Assignee: IBIDEN CO., LTD., Gifu (JP)

(21) Appl. No.: 19/266,992

(22) Filed: Jul. 11, 2025

Related U.S. Application Data
(63) Continuation of application No. PCT/JP2023/045719, filed on Dec. 20, 2023.

(30) Foreign Application Priority Data
Jan. 13, 2023 (JP) 2023-004075

(51) Int. Cl. H05K 1/02; H05K 1/18

(52) U.S. Cl. CPC H05K 1/0274; H05K 1/181

(57) ABSTRACT

A wiring substrate includes an electrical wiring part including an insulating layer and a conductor layer and having an optical wiring region and a component region, an optical wiring is formed on a surface of the electrical wiring part such that optical wiring is positioned in the optical wiring region of the electrical wiring part, and a support substrate formed on the optical wiring such that the support substrate is positioned in the optical wiring region of the electrical wiring part on the opposite side with respect to the electrical wiring part. The component region of the electrical wiring part positions a component on the surface of the electrical wiring part.

### CROSS-REFERENCE TO RELATED APPLICATIONS

The present application is a continuation of and claims the benefit of priority to International Application No. PCT/JP2023/045719, filed Dec. 20, 2023, which is based upon and claims the benefit of priority to Japanese Application No. 2023-004075, filed Jan. 13, 2023. The entire contents of these applications are incorporated herein by reference.

### BACKGROUND OF THE INVENTION

### Field of the Invention

The present invention relates to a wiring substrate.

### Description of Background Art

Japanese Patent Application Laid-Open Publication No. H05-196844 describes an optical component mounting substrate. The entire contents of this publication are incorporated herein by reference.

### SUMMARY OF THE INVENTION

According to one aspect of the present invention, a wiring substrate includes an electrical wiring part including an insulating layer and a conductor layer and having an optical wiring region and a component region, an optical wiring is formed on a surface of the electrical wiring part such that optical wiring is positioned in the optical wiring region of the electrical wiring part, and a support substrate formed on the optical wiring such that the support substrate is positioned in the optical wiring region of the electrical wiring part on the opposite side with respect to the electrical wiring part. The component region of the electrical wiring part positions a component on the surface of the electrical wiring part.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is an enlarged view of a portion (II) of FIG. 1;

FIG. 3 is a partial plan view illustrating an example of an optical wiring part of FIG. 1 in a plan view;

FIG. 4A is a cross-sectional view illustrating an example of a manufacturing process of an optical wiring part in a wiring substrate according to an embodiment of the present invention;

FIG. 4B is a cross-sectional view illustrating an example of a manufacturing process of an optical wiring part in a wiring substrate according to an embodiment of the present invention;

FIG. 4C is a cross-sectional view illustrating an example of a manufacturing process of an optical wiring part in a wiring substrate according to an embodiment of the present invention;

FIG. 5 is a cross-sectional view illustrating a first modified example of a wiring substrate according to an embodiment of the present invention;

FIG. 6A is an enlarged view illustrating an example of a portion (VI) of FIG. 5;

FIG. 6B is an enlarged view illustrating another example of the portion (VI) of FIG. 5;

FIG. 7 is a cross-sectional view illustrating a second modified example of a wiring substrate according to an embodiment of the present invention;

FIG. 8 is a cross-sectional view illustrating a third modified example of a wiring substrate according to an embodiment of the present invention;

FIG. 9A is an enlarged view illustrating an example of a portion (I) of FIG. 8;

FIG. 9B is an enlarged view illustrating another example of the portion (IX) of FIG. 8;

FIG. 10 is a cross-sectional view illustrating a fourth modified example of a wiring substrate according to an embodiment of the present invention; and

FIG. 11 is an enlarged view of a portion (XI) of FIG. 10; and

FIG. 12 is a partial plan view illustrating an example of an optical wiring part of FIG. 10 in a plan view.

### DETAILED DESCRIPTION OF THE EMBODIMENTS

Embodiments will now be described with reference to the accompanying drawings, wherein like reference numerals designate corresponding or identical elements throughout the various drawings.

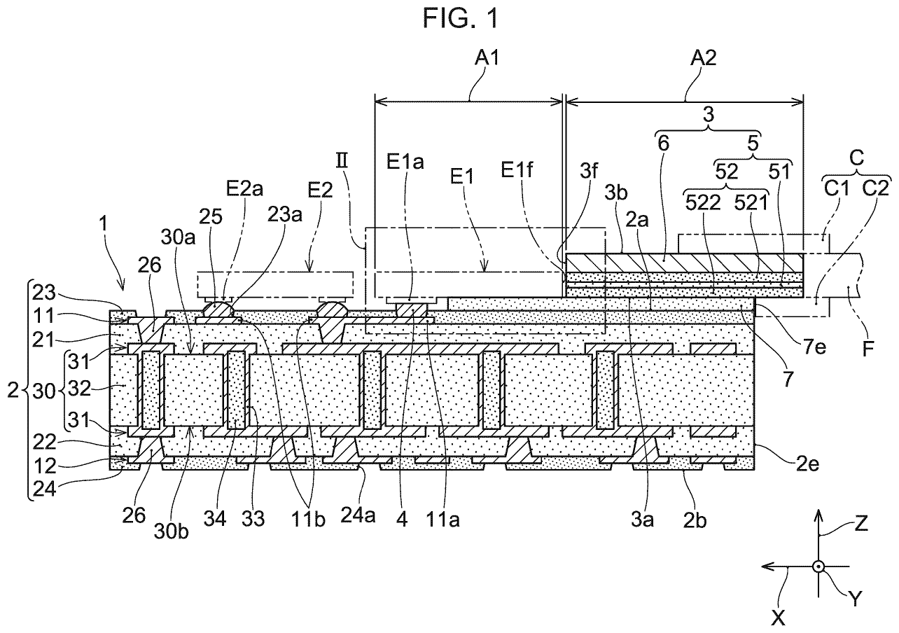

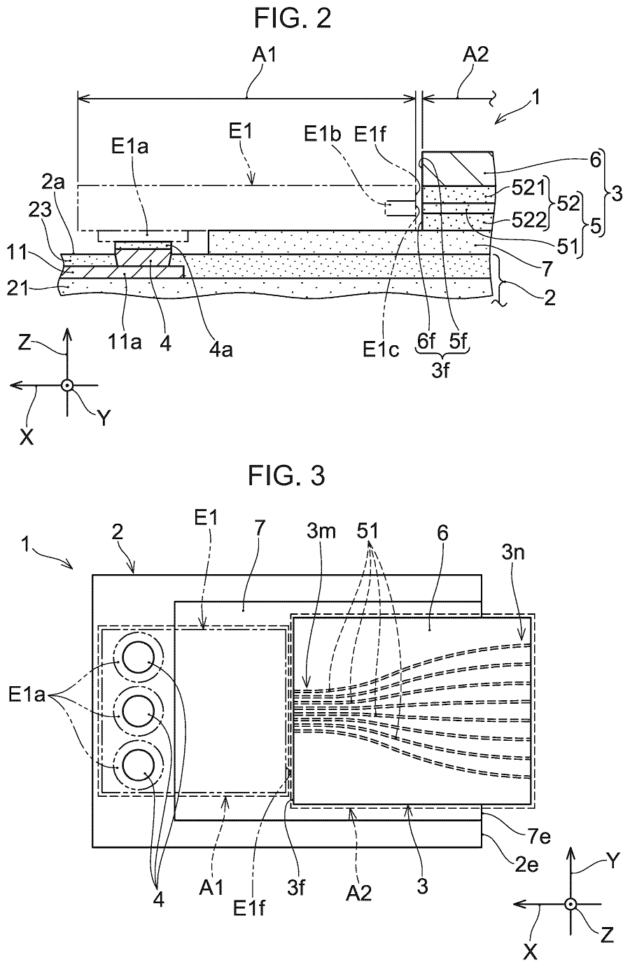

FIG. 1 is a cross-sectional view illustrating a wiring substrate 1 according to an embodiment of the present invention. FIG. 2 illustrates an enlarged view of a portion (II) of FIG. 1. FIG. 3 illustrates an example of an optical wiring part included in the wiring substrate 1 in FIG. 1 in a plan view. The term “plan view” means viewing the wiring substrate 1 of the embodiment along a thickness direction thereof. A laminated structure, and the number of conductor layers and the number of insulating layers of the wiring substrate of the embodiment are not limited to the laminated structure of the wiring substrate 1 of FIG. 1, and the number of conductor layers and the number of insulating layers included in the wiring substrate 1.

As illustrated in FIG. 1, the wiring substrate 1 includes an electrical wiring part 2. The electrical wiring part 2 includes insulating layers and conductor layers. Specifically, the electrical wiring part 2 in the example of FIG. 1 includes: a core substrate 30 that has two surfaces (30a, 30b) opposing each other in a thickness direction thereof; an insulating layer 21 and a conductor layer 11 that are sequentially laminated on the surface (3a) of the core substrate 30; and an insulating layer 22 and a conductor layer 12 that are sequentially laminated on the surface (30b) of the core substrate 30. In the insulating layer 21 and the insulating layer 22, via conductors 26 connecting conductor layers are formed. The core substrate 30 includes an insulating layer 32, and conductor layers 31 that are respectively formed on both sides of the insulating layer 32. The insulating layer 32 is provided with through-hole conductors 33 that penetrate the insulating layer 32 and connects the conductor layers 31 on both sides of the insulating layer 32 to each other. Inner sides of the tubular through-hole conductors 33 are filled with, for example, a filler 34 formed of an insulating resin such as an epoxy resin, or a conductive resin containing metal particles.

In the description of the embodiment, a side farther from the insulating layer 32 in the thickness direction of the wiring substrate 1 is also referred to as an “upper side” or simply “upper,” and a side closer to the insulating layer 32 is also referred to as a “lower side” or simply “lower.” Further, for the conductor layers and the insulating layers, a surface facing the opposite side with respect to the insulating layer 32 is also referred to as an “upper surface,” and a surface facing the insulating layer 32 side is also referred to as a “lower surface.” The thickness direction of the wiring substrate 1 is also referred to as a “Z direction.”

The electrical wiring part 2 includes a solder resist 23 formed on the surface (30a) side of the core substrate 30, and a solder resist 24 formed on the surface (30b) side of the core substrate 30. A surface (2a) of the electrical wiring part 2 is mainly constituted by an upper surface of the solder resist 23, and a surface (2b) of the electrical wiring part 2 is mainly constituted by an upper surface of the solder resist 24. The solder resist 23 covers necessary portions of the insulating layer 21 and the conductor layer 11, and the solder resist 24 covers necessary portions of the insulating layer 22 and the conductor layer 12. The solder resist 23 has openings (23a) that each expose a portion of the conductor layer 11. Similarly, the solder resist 24 also has openings (24a) that each expose a portion of the conductor layer 12.

The electrical wiring part 2 includes component (E1) connecting parts 4 and component (E2) connecting parts 25 that are formed in the openings (23a) of the solder resist 23 so as to be in contact the conductor layer 11. The component (E1) connecting parts 4 are, for example, conductor posts or conductive bumps. The conductor posts are formed, for example, using any metal such as copper or nickel. The conductive bumps are formed, for example, using tin-based solder, gold-based solder, or the like. When necessary, the component (E1) connecting parts 4 may each have a structure of two or more layers, for example, a two-layer structure including a conductor post and a conductive connecting member (4a) (see FIG. 2) formed on the conductor post using tin-based solder or gold-based solder. The component (E2) connecting parts 25 are, for example, conductor posts or conductive bumps. The conductor posts are formed, for example, using any metal such as copper or nickel. The conductive bumps are formed, for example, using tin-based solder, gold-based solder, or the like. The component (E2) connecting parts 25 are lower than the component (E1) connecting parts 4, and thus are preferably formed as conductive bumps.

The insulating layer 21, the insulating layer 22, and the insulating layer 32 can be formed, for example, using a thermosetting insulating resin such as an epoxy resin, a bismaleimide triazine resin (BT resin) or a phenol resin. It is also possible that the insulating layer 21, the insulating layer 22, and the insulating layer 32 are formed using a thermoplastic insulating resin such as a fluororesin, a liquid crystal polymer (LCP), a fluorinated ethylene (PTFE) resin, a polyester (PE) resin, or a modified polyimide (MPI) resin. Although not illustrated, the insulating layers each may contain a core material (reinforcing material) formed of a glass fiber, an aramid fiber, or the like, and each may contain an inorganic filler formed of fine particles of silica (SiO₂), alumina, mullite, or the like. On the other hand, the solder resist 23 and the solder resist 24 are formed of, for example, a photosensitive epoxy resin, a photosensitive polyimide resin, or the like.

The conductor layer 11, the conductor layer 12, the conductor layer 31, the through-hole conductors 33, and the via conductors 26 can be formed using any metal such as copper or nickel. In FIG. 1, these conductors are simplified and depicted as each having a one-layer structure. However, these conductors may each have a multilayer structure including two or more metal layers. For example, the conductor layer 11 and the conductor layer 12 may each have a two-layer structure including an electroless plating layer and an electrolytic plating layer.

The conductor layer 11, the conductor layer 12, and the conductor layer 31 each include any conductor patterns. In the example of FIG. 1, the conductor layer 11 includes conductor pads (11a) and conductor pads (11b). The conductor pads (11a) and the conductor pads (11b) are exposed in the openings (23a) of the solder resist 23. In this way, the electrical wiring part 2 in FIG. 1 has conductors exposed on the surface (2a), such as the conductor pads (11a) and the conductor pads (11b).

A component (E2) is electrically and mechanically connected to the conductor pads (11b) via the component (E2) connecting parts 25. The component (E2) can be, for example, an electronic component or the like, such as a semiconductor device that generates an electrical signal that causes a component (E1) to emit light, and/or processes an electrical signal generated by a component (E1). Examples of the component (E2) include semiconductor devices, such as a general-purpose operational amplifier, a driver IC, a microcomputer, and a programmable logic device (PLD). The component (E2) has, for example, electrodes (E2a).

As illustrated in FIGS. 1-3, when the wiring substrate 1 is used, the component (E1) is also mounted on the wiring substrate 1. Therefore, the surface (2a) of the electrical wiring part 2 has a component region (A1) in which the component (E1) can be positioned. The component (E1) is electrically and mechanically connected to the conductor pads (11a) via the component (E1) connecting parts 4. The component region (A1) is covered by the component (E1) in a plan view when the wiring substrate 1 is used. In the component region (A1), the component (E1) is positioned by the component (E1) connecting parts 4 and a support member 7. The component (E1) mounted in the component region (A1) is an electrical component that includes a light receiving element and/or a light emitting element and has a photoelectric conversion function. The component (E1) is provided with, for example, electrodes (Ela) and a light receiving or light emitting part (E1b) (see FIG. 2).

In the illustrated example, the light receiving or light emitting part (E1b) has a light receiving or light emitting surface (Elc) on an end surface (Elf) of the component (E1) (see FIG. 2), and the electrodes (Ela) are provided on a surface of the component (E1) facing the electrical wiring part 2 side. That is, in the example of FIGS. 1-3, the component (E1) is mounted by so-called face-down mounting (flip-chip mounting) such that the surface facing the electrical wiring part 2 side faces the support member 7, except for portions where the electrodes (Ela) are formed. It is also possible that the electrodes (Ela) of the component (E1) are provided on a surface of the component (E1) on the opposite side with respect to the surface facing the electrical wiring part 2 side, and the component (E1) is mounted by a so-called face-up mounting such that the surface facing the electrical wiring part 2 side faces the support member 7. In the case of the face-up mounting, the entire surface of the component (E1) facing the electrical wiring part 2 side may face the support member 7.

Examples of the component (E1) include: light receiving elements such as a photodiode; and light emitting elements such as a light emitting diode (LED), an organic light emitting diode (OLED), a laser diode (LD), and a vertical cavity surface emitting laser (VCSEL). When the component (E1) is a light emitting element, the component (E1) generates an optical signal (light) based on an electrical signal input to the electrodes (Ela), and emits light from the light receiving or light emitting part (E1b) (see FIG. 2) that functions as a light emitting part. Further, when the component (E1) is a light receiving element, an electrical signal is generated based on light incident on the light receiving or light emitting part (E1b) that functions as a light receiving part, and is output from the electrodes (Ela).

As illustrated in FIGS. 1-3, when the wiring substrate 1 is used, an optical wiring part 3 is also positioned on the wiring substrate 1. Therefore, the surface (2a) of the electrical wiring part 2 has an optical wiring region (A2) in which the optical wiring part 3 can be positioned. When the wiring substrate 1 is used, the optical wiring region (A2) is covered by the optical wiring part 3 in a planar view. In the optical wiring region (A2), the optical wiring part 3 is positioned on the support member 7. The optical wiring part 3 includes an optical wiring 5 and a support substrate 6. The optical wiring part 3 is positioned on the wiring substrate 1 such that the support substrate 6 is formed on the optical wiring 5 on the opposite side with respect to the electrical wiring part 2. That is, the optical wiring 5 is formed on the optical wiring region (A2), and the support substrate 6 is formed on the optical wiring 5. The support member 7 is formed between the electrical wiring part 2 and the optical wiring part 3. In the example of FIGS. 1-3, the support member 7 is positioned not only in the optical wiring region (A2) but also in the component region (A1). The optical wiring part 3 may be partially or entirely positioned on an upper surface of the support member 7.

The optical wiring 5 includes a core part 51 that transmits light and a cladding part 52 that surrounds the core part 51. The cladding part 52 is provided around the core part 51 and sandwiches the core part 51 in any direction perpendicular to an extension direction of the core part 51, that is, a light propagation direction in the core part 51 (+X or −X direction, hereinafter collectively referred to as the “X direction”).

The cladding part 52 includes a first cladding 521, which constitutes a portion closer to the support substrate 6 than the core part 51, and a second cladding 522, which constitutes a portion below the first cladding 521 and farther from the support substrate 6 than the first cladding 521. The second cladding 522 covers a lower surface (surface on the opposite side with respect to the support substrate 6) and side surfaces of the core part 51.

The core part 51 and the cladding part 52 are each formed using a material having an appropriate refractive index. The core part 51 and the cladding part 52 can each be formed of, for example, an organic material, an inorganic material, or a hybrid material, such as an inorganic polymer, containing an organic material and an inorganic material. Examples of inorganic materials include quartz glass, silicon, and the like, and examples of organic materials include acrylic resins such as polymethylmethacrylate (PMMA), polyimide resins, polyamide resins, polyether resins, epoxy resins, and the like. An optical wiring 5 constituted by an organic material tends to be lightweight and highly flexible.

The core part 51 and cladding part 52 may be constituted by materials different from each other, or may be constituted by materials of the same type. For the core part 51, a material having a higher refractive index than that used for the cladding part 52 is used so that total reflection of light at an interface between the core part 51 and the cladding part 52 is possible. It is also possible that, after the core part 51 and the cladding part 52 are formed using materials having the same refractive index, the refractive indices of the core part 51 and the cladding part 52 are made different from each other by appropriate processing.

The optical wiring 5 can be formed by any method. As an example, the optical wiring 5 can be formed on the support substrate 6. For example, the optical wiring 5 may be bonded to the support substrate 6 by curing the material of the cladding part 52 in a semi-cured state on the support substrate 6. Further, the optical wiring 5 may be formed separately from the support substrate 6 and fixed to the support substrate 6 with, for example, any adhesive (not illustrated). As in the example of FIGS. 1-3, in the optical wiring part 3 and the component (E1), when an end surface (3f) of the optical wiring part 3 and the end surface (Elf) of the component (E1) are optically connected to each other, an end surface (5f) of the optical wiring 5 and an end surface (6f) of the support substrate 6 can be formed flush with each other (see FIG. 2). That is, the end surface (3f) of the optical wiring part 3, which is constituted by the end surface (5f) of the optical wiring 5 and the end surface (6f) of the support substrate 6, can be formed as a planar surface.

The support substrate 6 has, for example, a thermal expansion coefficient lower than that of the optical wiring 5. When the core part 51 and the cladding part 52 have different thermal expansion coefficients, the support substrate 6 has, for example, a thermal expansion coefficient lower than an average value of the thermal expansion coefficients of the core part 51 and the cladding part 52. Preferably, the thermal expansion coefficient of the support substrate 6 is lower than the lower of the thermal expansion coefficients of the core part 51 and the cladding part 52. In this way, the support substrate 6 can be constituted by any material so as to have a lower thermal expansion coefficient than the optical wiring 5 and preferably have a higher rigidity than the optical wiring 5. For example, the support substrate 6 may have a higher bending rigidity than the optical wiring 5. Examples of the material of the support substrate 6 include glasses such as soda-lime glass, borosilicate glass, and quartz glass; various ceramics such as alumina, silicon nitride, and silicon oxide; and semiconductors such as silicon and germanium.

The thermal expansion coefficient of the optical wiring 5 is, for example, 10 ppm/° C.-100 ppm/° C. In contrast, the thermal expansion coefficient of the support substrate 6 is, for example, 3 ppm/° C.-10 ppm/° C. The bending rigidity of the support substrate 6 is, for example, 1.1 or more times the bending rigidity of the optical wiring 5, and 2 or less times the bending rigidity of the electrical wiring part 2. It is thought that the optical wiring 5 can be handled and maintained in shape and that the optical wiring part 3 can follow the warping of the electrical wiring part 2 to some extent. A thickness of the support substrate 6 is not particularly limited, but may be, for example, about 30 μm or more and 1000 μm or less.

The support member 7 that supports the component (E1) and the optical wiring part 3 is formed on the surface (2a) of the electrical wiring part 2. Specifically, it is formed on the upper surface of the solder resist 23. In the example of FIGS. 1-3, the support member 7 is formed so as to span across the component region (A1) and the optical wiring region (A2). Therefore, in the example of FIGS. 1-3, when the wiring substrate 1 is used, the component (E1) and the optical wiring part 3 are positioned on the wiring substrate 1, on a common support member 7. In the illustrated example, the support member 7 is formed in the component region (A1) and the optical wiring region (A2) in a plan view. That is, the support member 7 is formed to partially cover the component region (A1) and the optical wiring region (A2) in a plan view. The support member covering the component region (A1) and the optical wiring region (A2) is not particularly limited in shape or size. Then, the component (E1) connecting parts 4 are formed on the surface (2a) of the electrical wiring part 2 adjacent to the support member 7. As a result, the adjacent component (E1) connecting parts 4 are connected to the electrodes (Ela) of the component (E1). It is also possible that the support member 7 is formed on the surface (2a) of the electrical wiring part 2 where the solder resist 23 is not formed.

The shape and size of the support member 7 can be appropriately modified depending on the shape and size of the component region (A1) and the shape and size of the optical wiring region (A2), as well as the positioning of the component region (A1) on the electrical wiring part 2 and the positioning of the optical wiring region (A2) on the electrical wiring part 2. For example, when the component (E1) is mounted on the electrical wiring part 2 by the so-called face-up mounting, the support member 7 may be formed in the entire component region (A1). Further, when the entire optical wiring part 3 is positioned on the surface (2a) of the electrical wiring part 2, the support member 7 may be formed in the entire optical wiring region (A2). In the illustrated example, an end surface (7e) of the support member 7 is near an end surface (2e) of the electrical wiring part 2 (see FIGS. 1 and 3). Specifically, the end surface (7e) of the support member 7 is substantially flush with the end surface (2e) of the electrical wiring part 2. It is also possible that the end surface (7e) of the support member 7 is formed on an inner side of the end surface (2e) of the electrical wiring part 2, or the end surface (7e) of the support member 7 is formed to protrude beyond the end surface (2e) of the electrical wiring part 2.

The support member 7 is not particularly limited but has, for example, a plate-like shape or a film-like shape. The support member 7 may have a rigidity sufficient to maintain a predetermined thickness. As an example, the support member 7 has a film-like shape. When a film is used, a surface of the support member 7 facing the electrical wiring part 2 side may have adhesiveness so that it can be fixed to the electrical wiring part 2. Further, when a film is used, a surface of the support member 7 on the opposite side with respect to the surface facing the electrical wiring part 2 side (surface facing the component (E1) side and the optical wiring part 3 side) may have adhesiveness so that it can be fixed to the component (E1) and the optical wiring part 3.

A material constituting the support member 7 is not particularly limited, but is a resin material, a metal material, an inorganic material, or a composite of these materials. A resin material is preferably used as the material constituting the support member 7. Examples of the resin material constituting the support member 7 include thermosetting resins, thermoplastic resins, UV-curable resins, and the like. Further, these resins may each be independently used, or two or more of these resins may be used in combination. Examples of combinations of multiple resins include a combination of a thermosetting resin and a UV-curable resin, a combination of a thermosetting resin and a thermoplastic resin, and the like. Specific examples of the resin forming the support member 7 are not particularly limited, but include an epoxy resin, a polyester resin, a polyimide resin, an olefin resin, and the like. A thermosetting resin constituting the support member 7 is not particularly limited, but examples thereof include an epoxy resin, a polyester resin, a polyimide resin, an olefin resin, a phenol resin, a polyurethane resin, a silicone resin, and the like. A thermoplastic resin constituting the support member 7 is not particularly limited, but examples thereof include a polyethylene resin, a polypropylene resin, a polyvinyl chloride resin, a polystyrene resin, an ABS resin, a methacrylic resin, an acrylic resin, a polyacetal resin, a polycarbonate resin, a PET resin, a PPS resin, a polystyrene resin, and the like. A UV-curable resin constituting the support member 7 is not particularly limited, but examples thereof include an epoxy resin, an acrylic resin, and the like. An acrylic group may be substituted for a part of the thermosetting resin.

When the material constituting the support member 7 is a resin material, a glass transition temperature thereof is preferably 50° C. to 200° C. A thermal expansion coefficient of the support member 7 is, for example, 30 ppm/° C. to 200 ppm/° C. The thickness of the support member 7 is not particularly limited, but is about 5 μm or more and 200 μm or less.

The support member 7 may contain particles such as inorganic particles, metal particles, or resin particles. Sizes of the particles contained in the support member are not particularly limited, but are, for example, about 0.1 μm or more and 20 μm or less. By containing particles in the support member 7, the rigidity and heat resistance of the support member are improved.

The support member 7 may have a single-layer structure or a multilayer structure of two or more layers. When the support member 7 has a single-layer structure, the support member 7 is formed on the wiring substrate 1, for example, by forming a film by film lamination, printing or potting, or the like, or by placing a pre-formed sheet. When the support member 7 has a multi-layer structure, the support member 7 is formed to have, for example, a two-layer structure in which an adhesive layer is provided on one side of a resin layer serving as a base layer, or a three-layer structure in which adhesive layers are respectively provided on both sides of a resin layer serving as a base layer. When the support member 7 has a two-layer structure, the support member 7 is formed such that, for example, an adhesive layer on one side of the support member 7 faces the electrical wiring part 2 side. The support member 7 is bonded to the electrical wiring part 2 by the adhesive layer. When the support member 7 has a three-layer structure, the support member 7 is formed such that an adhesive layer provided on one side of the support member 7 faces the electrical wiring part 2 side, and an adhesive layer provided on the other side of the support member 7 faces the component (E1) side and the optical wiring part 3 side. The support member 7 is bonded to the electrical wiring part 2 and to the component (E1) and the optical wiring part 3 by the adhesive layers.

A metal material forming the support member 7 is not particularly limited, but examples thereof include copper, aluminum, nickel, titanium, beryllium, iron, platinum, stainless steel, and the like. The support member 7 may be constituted by covering a metal material serving as a core material with a resin material, or may be formed of two or more layers including a layer formed of a metal material and a layer formed of a resin material having adhesiveness to the metal material. By using a metal material, a heat dissipation property can be imparted to the support member 7.

An inorganic material constituting the support member 7 is not particularly limited, but examples thereof include glass, semiconductor materials, and the like. The support member 7 may be constituted by covering an inorganic material serving as a core material with a resin material, or may be constituted by two or more layers including a layer formed of an inorganic material and a layer formed of a resin material having adhesiveness to the inorganic material. By using an inorganic material, rigidity and thermal expansion resistance can be imparted to the support member 7.

With continued reference to FIGS. 2 and 3, an example of a form of optical and electrical connection between the electrical wiring part 2, the component (E1), and the optical wiring part 3 is further described. As illustrated in FIG. 2, a height (dimension in the Z direction) of the component (E1) connecting parts 4 of the electrical wiring part 2 is adjusted such that a lower surface of the component (E1) aligns with the upper surface of the support member 7. Further, the position of the core part 51 of the optical wiring part 3 is adjusted to align with a position of the light receiving or light emitting part (E1b) of the component (E1) in the thickness direction (Z direction) of the electrical wiring part 2. As illustrated in FIGS. 2 and 3, when positioned on the wiring substrate 1, the component (E1) and the optical wiring part 3 are positioned on the common support member 7 that spans across the component region (A1) and the optical wiring region (A2) on the surface (2a) of the electrical wiring part 2. The optical wiring part 3 and the component (E1) are positioned on the surface (2a) of the electrical wiring part 2 such that the light receiving or light emitting part (E1b) and the core part 51 are optically coupled while being positioned on the common support member 7. Therefore, it is thought that, after being positioned on the wiring substrate 1, a positional misalignment in the Z direction between the light receiving or light emitting part (E1b) of the component (E1) and the core part 51 of the optical wiring part 3, both positioned on the common support member 7, is reduced.

That is, when the support substrate 6 is not formed above the optical wiring 5, the optical wiring 5 is not pressed downward by the weight of the support substrate 6. Since the optical wiring part 3 is not pressed by the support substrate 6, in an environment in which the optical wiring 5 expands and contracts, the expansion and contraction of the optical wiring 5 may cause an increase in difference in dimensional error in the Z direction. Therefore, the optical coupling efficiency between the optical wiring part 3 and the component (E1) may decrease. In contrast, in the present embodiment, since the support substrate 6 is formed above the optical wiring 5, it is thought that even in an environment in which the optical wiring 5 expands and contracts, the optical wiring 5 is pressed downward by the weight of the support substrate 6, and thus, is less susceptible to a dimensional change. Therefore, it is thought that the core part 51 of the optical wiring part 3 and the light receiving or light emitting part (E1b) of the component (E1) can be easily positioned at positions that allow optical coupling with sufficient efficiency to be achieved. In particular, when an organic material is used for the optical wiring 5, the optical wiring 5 becomes more susceptible to expansion and contraction. Further, in the present embodiment, since the optical wiring 5 is pressed downward by the weight of the support substrate 6 and thus is less susceptible to a dimensional change, it is thought that a positional misalignment in the Z direction with respect to the core part 51 of the optical wiring part 3 is small.

When being positioned on the wiring substrate 1, the optical wiring part 3 and component (E1) may be externally heated, for example, during a reflow process or the like. Further, the optical wiring part 3 may generate heat due to propagation of light in the core part 51, and the component (E1) may generate heat due to light reception from the core part 51 or light emission to the core part 51. In this way, it is thought that the optical wiring part 3 and the component (E1) can be thermally affected due to external heating during or after positioning on the wiring substrate 1, or due to heat generated from the optical wiring part 3 and the component (E1). When the optical wiring 5 is not formed on the support substrate 6, it is thought that the optical wiring part 3 thermally expands due to external heating during and after positioning on the wiring substrate 1 and heat generated by the optical wiring part 3 and the component (E1).

When the optical wiring part 3 thermally expands, the core part 51 may follow an expansion direction and thus move in a direction different from a desired position. Therefore, it may be possible that misalignment between the position of the core part 51 of the optical wiring part 3 and the position of the light receiving or light emitting part (E1b) of the component (E1) occurs not only in the Z direction but also in a direction along the surface (2a) of the electrical wiring part 2 (X direction and Y direction). Therefore, the optical coupling efficiency between the optical wiring part 3 and the component (E1) may decrease.

In contrast, in the present embodiment, the support substrate 6 is formed above the optical wiring 5. Therefore, it is thought that, even in an environment in which the optical wiring 5 expands and contracts due to external heating during and after positioning on the wiring substrate 1 and due to heat generated by the optical wiring part 3 and the component (E1), expansion and contraction of the optical wiring 5 are suppressed also in the X and Y directions due to the downward pressing of the optical wiring 5 by the weight of the support substrate 6. Therefore, it is thought that the relative position between the core part 51 of the optical wiring part 3 and the light receiving or light emitting part (E1b) of the component (E1) is unlikely to change even in the X and Y directions. As a result, it is thought that when the optical wiring part 3 and the component (E1) are positioned at positions that allow optical coupling with sufficient efficiency to be achieved, a decrease in optical coupling efficiency between the optical wiring part 3 and the component (E1) is suppressed during and after the positioning on the wiring substrate 1.

Further, in the present embodiment, the optical wiring part 3 and the component (E1) are positioned on the common support member 7 that spans across the component region (A1) and the optical wiring region (A2). Therefore, the support member 7 is thermally affected due to external heating during or after positioning on the wiring substrate 1 or due to heat generated by the optical wiring part 3 and the component (E1). Even when the support member 7 expands due to a thermal effect, it is thought that the optical wiring part 3 and the component (E1) move in the same direction by the common support member 7 that spans across the component region (A1) and the optical wiring region (A2). Therefore, it is thought that the relative position between the core part 51 of the optical wiring part 3 and the light receiving or light emitting part (E1b) of the component (E1) is unlikely to change even when the support member 7 expands. As a result, it is thought that when the optical wiring part 3 and the component (E1) are positioned at positions that allow optical coupling with sufficient efficiency to be achieved, a decrease in optical coupling efficiency between the optical wiring part 3 and the component (E1) is suppressed during and after the positioning.

As illustrated in FIG. 3, the optical wiring part 3 of FIGS. 1-3 includes multiple core parts 51. The multiple core parts 51 are formed side by side along a direction intersecting the light propagation direction (X direction) in the core parts 51. Then, in the example of FIG. 3, spacings between the multiple core parts 51 increase as they approach from one end part (3m) to the other end part (3n). Therefore, a spacing of the core parts 51 at the other end (3n) of the optical wiring part 3 is larger than a spacing of the core parts 51 at the end (3m) of the optical wiring part 3. For example, it may be possible that multiple optical fibers optically coupled to the core parts 51 at the other end part (3n) cannot be formed at a spacing as small as a spacing of multiple light receiving or light emitting parts (E1b) (see FIG. 2) provided in the component (E1). In the example of FIG. 3, the multiple core parts 51 are formed at a larger spacing at the other end (3n) of the optical wiring part 3 than at the end (3m) of the optical wiring part 3. The core parts 51 at the end (3m) of the optical wiring part 3 are optically coupled to the component (E1) (see FIG. 2), and it is thought that the optical coupling can be appropriately achieved without requiring any separate conversion measure such as a spacing conversion measure. Further, the core parts 51 at the other end (3n) of the optical wiring part 3 are externally connected via optical fibers or the like, and it is thought that the optical coupling can be appropriately achieved without requiring any other conversion measure such as a spacing conversion measure.

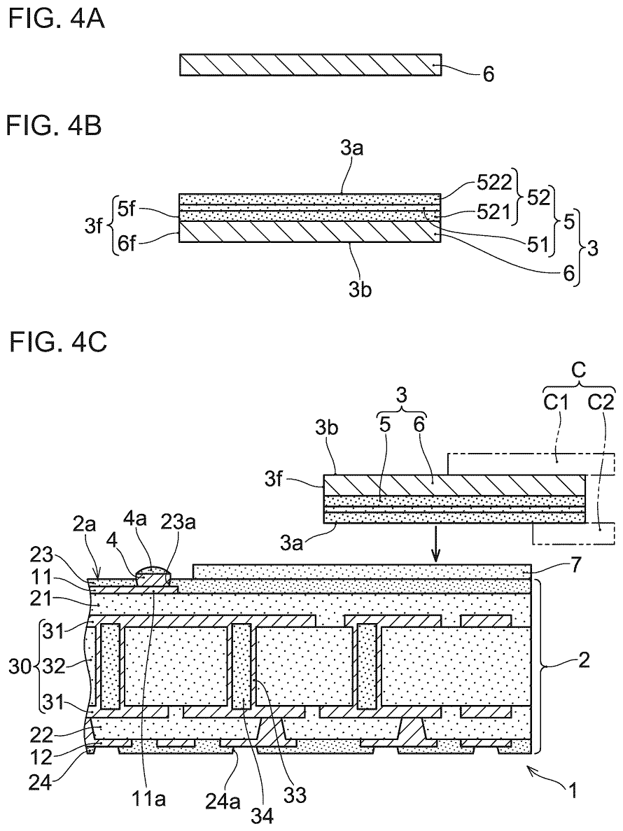

Next, an example of a method for manufacturing a wiring substrate according to an embodiment of the present invention is described with reference to FIGS. 4A-4C, using a case where the wiring substrate 1 of FIG. 1 is manufactured as an example.

First, the optical wiring part 3 is manufactured. As illustrated in FIG. 4A, for example, a glass plate, a ceramic plate, or a semiconductor substrate of silicon or the like, is prepared as the support substrate 6.

Next, as illustrated in FIG. 4B, the optical wiring 5 is formed on a surface of the support substrate 6. Specifically, first, the first cladding 521 of the cladding part 52 is formed on the surface of the support substrate 6. The first cladding 521 is formed, for example, using a resin material. The first cladding 521 is formed, for example, by coating such as spin coating, or by film lamination or the like. When molded using a film, the first cladding 521 is thermocompression bonded onto the surface of the support substrate 6.

After that, the core part 51 is formed on the first cladding 521. The core part 51 is formed, for example, using a resin material. The core part 51 is formed, for example, by coating such as spin coating, or by film lamination or the like. When molded using a film, the core part 51 is thermocompression bonded onto the entire surface of the first cladding 521 and is patterned into desired shape and number of core parts 51 by photolithography.

Next, the second cladding 522 is formed on the first cladding 521 and the core part 51. The second cladding 522 is formed, for example, using a resin material. The second cladding 522 is formed, for example, by coating such as spin coating, or by film lamination or the like. When molded using a film, the second cladding 522 is thermocompression bonded onto the first cladding 521 and the core part 51. As a result, the cladding part 52 formed of the first cladding 521 and the second cladding 522 is formed. After that, the core part 51, the cladding part 52, and the support substrate 6 are diced by cutting or laser processing, or the like, so as to have predetermined shapes and sizes in a plan view. Through the above processes, the optical wiring part 3 formed of the optical wiring 5 and the support substrate 6 is completed. The end surface (5f) of the optical wiring 5 and the end surface (6f) of the support substrate 6, which form the end surface (3f) of the obtained optical wiring part 3, are formed flush with each other by the dicing.

FIG. 4C illustrates a method for manufacturing the wiring substrate 1 and a method for arranging the optical wiring part 3 on the wiring substrate 1. In manufacturing the wiring substrate 1, first, the electrical wiring part 2 is prepared. The electrical wiring part 2 may be prepared, for example, using a general method for forming a build-up wiring substrate including a core substrate. For example, the core substrate 30 is formed by forming the through-hole conductors 33 in a double-sided copper-clad laminate including the insulating layer 32, and by forming the conductor layers 31 using a subtractive method. Then, the insulating layer 21, the insulating layer 22, the conductor layer 11, the conductor layer 12, and the via conductors 26 (see FIG. 1) are formed by thermocompression bonding insulating resin films onto both sides of the core substrate 30 and forming conductor layers using a semi-additive method. Further, the solder resist 23 and the solder resist 24 are formed by laminating an epoxy resin, a polyimide resin, or the like, or coating with these resins, and the openings (23a) and the openings (24a) are formed, for example, by photolithography. Then, in the openings (23a) that expose the conductor pads (11b), the component (E1) connecting parts 4 are formed by plating as conductor posts formed of copper or nickel. When necessary, the conductive connecting member (4a) formed of a tin-based solder or a gold-based solder is formed on the component (E1) connecting parts 4, for example, by applying a paste containing metal powder and performing a reflow process. Although not illustrated in FIG. 4C, in the openings (23a) that expose the conductor pads (11b), the component (E2) connecting parts 25 are formed as conductive bumps formed of a tin-based solder or a gold-based solder, for example, by arranging balls and performing a reflow process (see FIG. 1)

Next, the support member 7 is provided on the surface (2a) of the electrical wiring part 2. For example, the support member 7 formed in a film-like shape is positioned on the surface (2a). The support member 7 is formed of, for example, any plate-like member of a material containing an epoxy resin and inorganic particles, or the like. The support member 7 may be fixed to the electrical wiring part 2.

Next, as illustrated in FIG. 4C, the optical wiring part 3 is positioned on the support member 7. When positioned on the support member 7, the surface (3a) of the optical wiring part 3 on the optical wiring 5 side and the surface (3b) of the optical wiring part 3 on the support substrate 6 side are flipped upside down (see FIGS. 4B and 4C). That is, the optical wiring 5 of the optical wiring part 3 faces the support member 7 formed on the surface (2a) of the electrical wiring part 2. After that, the optical wiring part 3 is positioned on the support member 7. The optical wiring part 3 may be fixed to the support member 7. Further, after the optical wiring part 3 is attached to the support member 7 via an adhesive, a combined component of the optical wiring part 3 and the support member 7 may be positioned on the surface (2a) of the electrical wiring part 2. Through the above processes, the wiring substrate 1 is completed. When necessary, the connector (C) is provided such that the optical wiring part 3 is sandwiched between the upper housing (C1) and the lower housing (C2). For example, the upper housing (C1) is attached to the support substrate 6, and the lower housing (C2) is attached to the optical wiring 5. In the process of attaching the connector (C) to the optical wiring part 3, the upper housing (C1) and the lower housing (C2) are fitted together. It is also possible that the connector (C) is attached after the optical wiring part 3 is provided on the surface (2a) of the electrical wiring part 2. It is also possible that the optical wiring part 3 is positioned on the wiring substrate 1 without using the support member 7.

After that, as illustrated in FIG. 1, the component (E1) including an optical element is positioned on the wiring substrate 1. The component (E2) may be mounted together with the component (E1). The electrodes (Ela) of the component (E1) are connected to the component (E1) connecting parts 4 by, for example, the conductive connecting members (4a), which are on the component (E1) connecting parts 4 and melt during mounting. On the other hand, the light receiving or light emitting part (E1b) is optically coupled to an exposed portion of the core part 51 of the optical wiring part 3. According to the present embodiment, it is thought that both an appropriate optical coupling between the light receiving or light emitting part (E1b) of the component (E1) and the core part 51 of the optical wiring part 3 and a reliable electrical and mechanical connection between the electrodes (Ela) of the component (E1) and the component (E1) connecting parts 4 are achieved. It is also possible that the component (E1) is positioned on the wiring substrate 1 without using the support member 7. Further, it is also possible that the optical wiring part 3 is positioned on the wiring substrate 1 without using the support member 7, while the component (E1) is positioned using the support member 7. Further, it is also possible that the optical wiring part 3 is positioned on the wiring substrate 1 using the support member 7, while the component (E1) is positioned without using the support member 7.

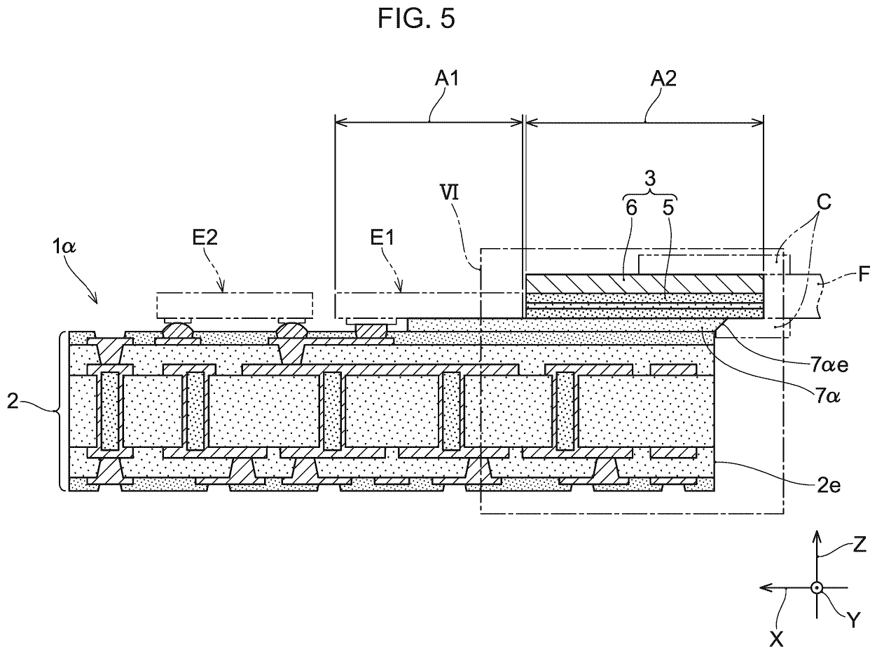

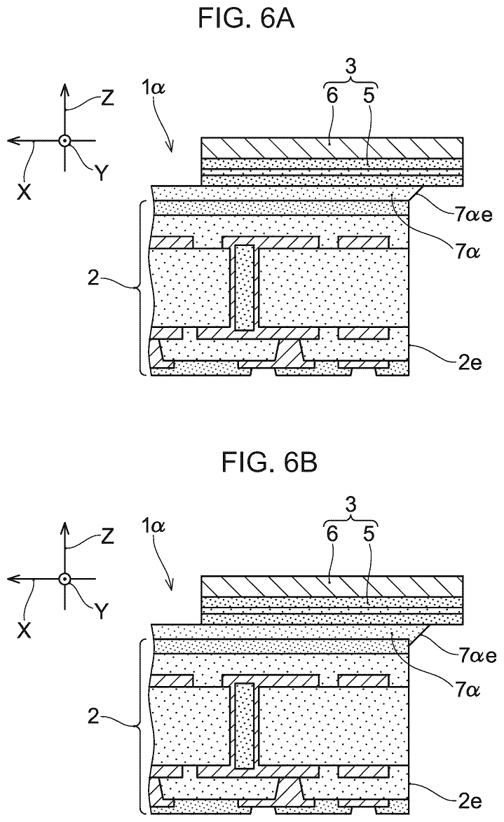

FIGS. 5-6B illustrate a wiring substrate (la), which is a first modified example of the wiring substrate of the embodiment. FIG. 5 is a cross-sectional view illustrating the wiring substrate (la), which is the first modified example of the wiring substrate of the embodiment. FIG. 6A illustrates an example of an enlarged view of a portion (VI) of FIG. 5, and FIG. 6B illustrates another example of an enlarged view of the portion (VI) of FIG. 5. In FIGS. 5-6B, a structural element that is the same as a structural element illustrated in FIGS. 1-3 is indicated using the same reference numeral symbol as the one used in FIGS. 1-3, and repeated description thereof is omitted as appropriate. Further, in FIGS. 6A and 6B, the two-dot chain lines in FIG. 5 are omitted for convenience of description.

The wiring substrate (la) includes an electrical wiring part 2 similar to the electrical wiring part 2 included in the wiring substrate 1 in FIGS. 1-3. In the wiring substrate (la) in FIGS. 5-6B, different from the wiring substrate 1 in FIGS. 1-3, a support member (7a) extends to an outer side of the end surface (2e) of the electrical wiring part 2. Therefore, the support member (7a) is formed so as to protrude beyond the end surface (2e) of the electrical wiring part 2. When the support member (7a) protrudes beyond the end surface (2e) of the electrical wiring part 2, an area for supporting the optical wiring part 3 by the support member (7a) increases by the amount that the support member (7a) protrudes beyond the end surface (2e) of the electrical wiring part 2. In other words, an area for bonding the optical wiring part 3 by the support member (7a) increases. Therefore, it is thought that the support of the optical wiring part 3 by the support member (7a) becomes more stable, or the bonding becomes more stable. Specifically, in the example of FIG. 6A, the support member (7a) is formed such that an end face (7ae) of the support member (7a) protrudes from the end surface (2e) of the electrical wiring part 2. On the other hand, in the example of FIG. 6B, the support member (7a) is formed such that the end surface (7ae) of the support member (7a) protrudes from the end surface (2e) of the electrical wiring part 2 and covers a part of the end surface (2e) of the electrical wiring part 2. As illustrated in FIG. 6B, since the support member (7a) covers a part of the end surface (2e) of the electrical wiring part 2, an area for supporting the support member (7a) by the electrical wiring part 2 is increased. In other words, an area for bonding the optical wiring part 3 by the support member (7a) increases. Therefore, it is thought that the support of the optical wiring part 3 by the electrical wiring part 2 becomes more stable, or the bonding becomes more stable.

Further, also in the wiring substrate (la), similar to the wiring substrate 1 of FIGS. 1-3, since the optical wiring 5 is formed on the support substrate 6 above it, it is thought that, due to the downward pressing by the weight of the support substrate 6, the optical wiring 5 is unlikely to expand and contract in the X, Y, and Z directions. Therefore, it is thought that a decrease in optical coupling efficiency between the optical wiring part 3 and the component (E1) is suppressed during and after the positioning.

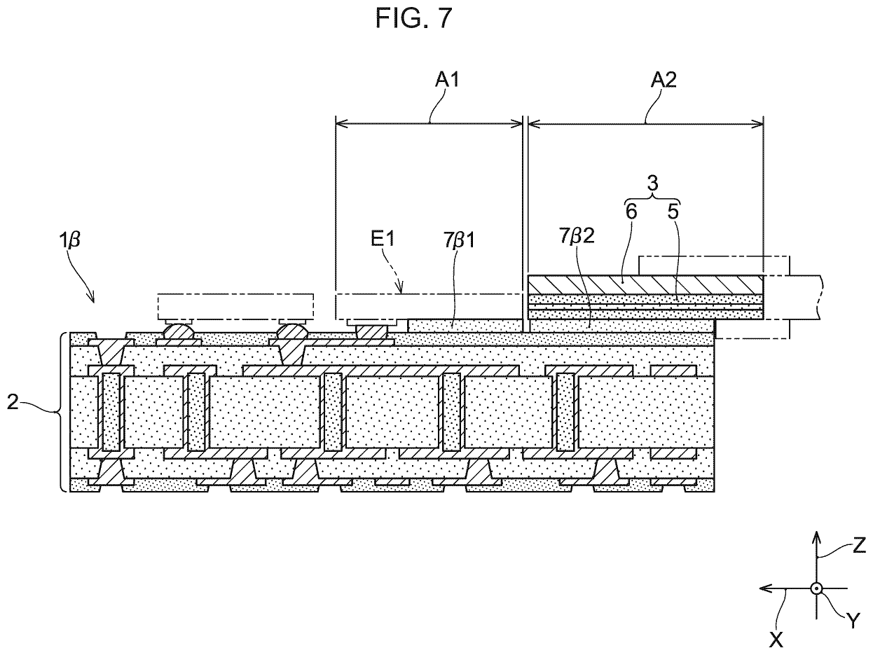

FIG. 7 illustrates a wiring substrate (1β), which is a second modified example of the wiring substrate of the embodiment. FIG. 7 is a cross-sectional view illustrating the wiring substrate (1β), which is the second modified example of the wiring substrate of the embodiment. In FIG. 7, a structural element that is the same as a structural element illustrated in FIGS. 1-3 is indicated using the same reference numeral symbol as the one used in FIGS. 1-3, and repeated description thereof is omitted as appropriate.

The wiring substrate (1B) includes an electrical wiring part 2 similar to the electrical wiring part 2 included in the wiring substrate 1 in the example of FIGS. 1-3. In the wiring substrate (1B) in the example of FIG. 7, different from the wiring substrate 1 in the example of FIGS. 1-3, a support member (7β2) supports only the optical wiring part 3, and a support member (7β1) different from the support member (7β2) supports the component (E1). In the following, the member supporting the optical wiring part 3 is also referred to as the optical wiring part support member (7β2), and the member supporting the component (E1) is also referred to as the component support member (7β1).

The component support member (7β1) is positioned in the component region (A1), and the optical wiring part support member (7β2) is formed in the optical wiring region (A2). Materials forming the component support member (7β1) and the optical wiring part support member (7β2) are not particularly limited, but may be, for example, the same material as the support member 7 of FIGS. 1-3. The materials forming the component support member (7β1) and the optical wiring part support member (7β2) may be the same or different from each other.

Also in the wiring substrate (1β) in the example of FIG. 7, the optical wiring 5 is formed on the support substrate 6 above it. Therefore, it is thought that, even in an environment in which the optical wiring 5 expands and contracts due to external heating during and after the positioning of the optical wiring 5 and due to heat generated by the optical wiring 5, the optical wiring 5 is unlikely to expand and contract in the X, Y, and Z directions due to the downward pressing of the optical wiring 5 by the weight of the support substrate 6. Therefore, it is thought that a decrease in optical coupling efficiency between the optical wiring part 3 and the component (E1) is suppressed during and after the positioning of the optical wiring 5.

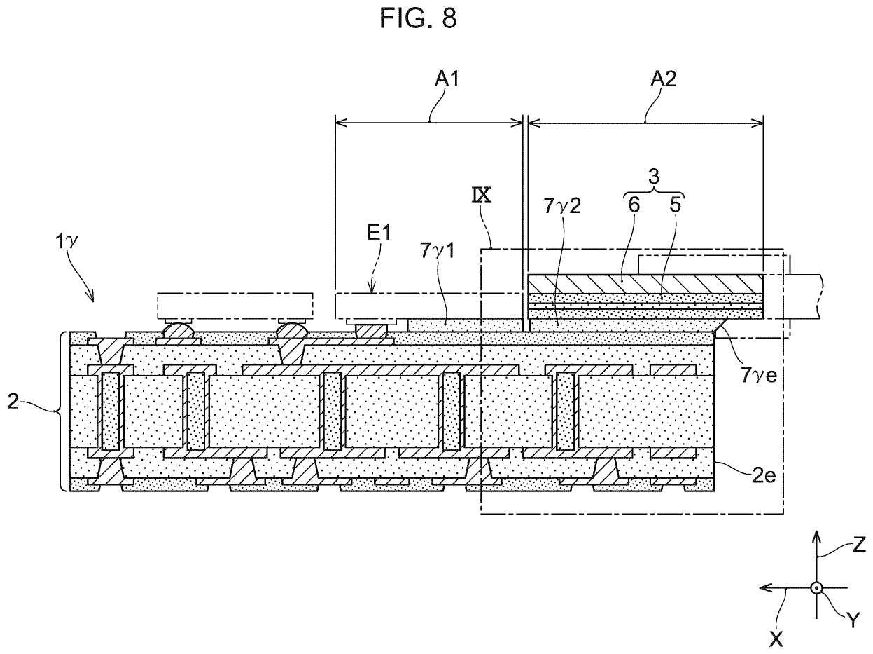

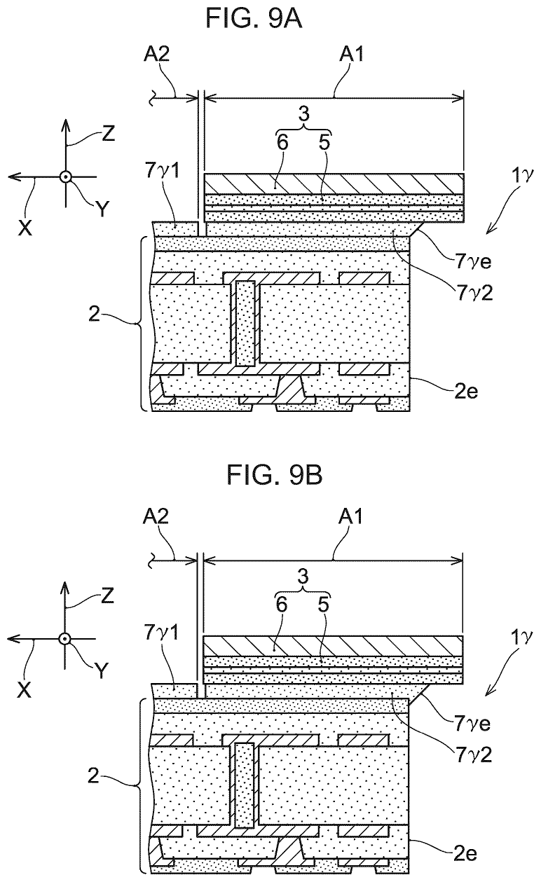

FIGS. 8-9B illustrate a wiring substrate (1γ), which is a third modified example of the wiring substrate of the embodiment. FIG. 8 is a cross-sectional view illustrating the wiring substrate (1γ), which is the third modified example of the wiring substrate of the embodiment. FIG. 9A illustrates an example of an enlarged view of a portion (IX) of FIG. 8, and FIG. 9B illustrates another example of an enlarged view of the portion (IX) of FIG. 8. In FIGS. 8-9B, a structural element that is the same as a structural element illustrated in FIGS. 1-3 is indicated using the same reference numeral symbol as the one used in FIGS. 1-3, and repeated description thereof is omitted as appropriate. Further, in FIGS. 9A and 9B, the two-dot chain lines in FIG. 8 are omitted for convenience of description.

The wiring substrate (1γ) includes an electrical wiring part 2 similar to the electrical wiring part 2 included in the wiring substrate 1 in the example of FIGS. 1-3. In the wiring substrate (1γ) in the example of FIG. 8, different from the wiring substrate 1 in the example of FIGS. 1-3, and similar to the wiring substrate (1β) in the example of FIG. 7, a component support member (7γ1) and an optical wiring part support member (7γ2) are separately provided in the component region (A1) and in the optical wiring region (A2), respectively. Further, in the wiring substrate (1γ) in the example of FIG. 8, different from the wiring substrate (1β) in the example of FIG. 7, and similar to the wiring substrate (la) in the example of FIGS. 5-6B, the optical wiring part support member (7γ2) is formed so as to protrude beyond the end surface (2e) of the electrical wiring part 2. A protruding shape of the optical wiring part support member (7γ2) is not particularly limited. The optical wiring part support member (7γ2) may be formed such that an end surface (7γe) thereof protrudes beyond the end surface (2e) of the electrical wiring part 2, as illustrated in FIG. 9A, or may be formed to cover a part the end surface (2e) of the electrical wiring part 2, as shown in FIG. 9B.

Also in the wiring substrate (17) in the example of FIGS. 8-9B, similar to the wiring substrate (la) of FIGS. 5-6B, the optical wiring part support member (7γ2) is formed such that the end surface (7γe) protrudes beyond the end surface (2e) of the electrical wiring part 2. Therefore, it is thought that the support (or bonding) of the optical wiring part 3 by the optical wiring part support member (7γ2) becomes more stable. As illustrated in FIG. 9B, since the optical wiring part support member (7γ2) also covers a part of the end surface (2e) of the electrical wiring part 2, it is thought that the support of the optical wiring part support member (7γ2) by the electrical wiring part 2 becomes more stable, or the bonding becomes more stable.

Further, also in the wiring substrate (1γ), similar to the wiring substrate 1 of FIGS. 1-3, since the optical wiring 5 is formed on the support substrate 6 above it, it is thought that, due to the downward pressing by the weight of the support substrate 6, the optical wiring 5 is unlikely to expand and contract in the X, Y, and Z directions. Therefore, it is thought that a decrease in optical coupling efficiency between the optical wiring part 3 and the component (E1) is suppressed during and after the positioning of the optical wiring 5.

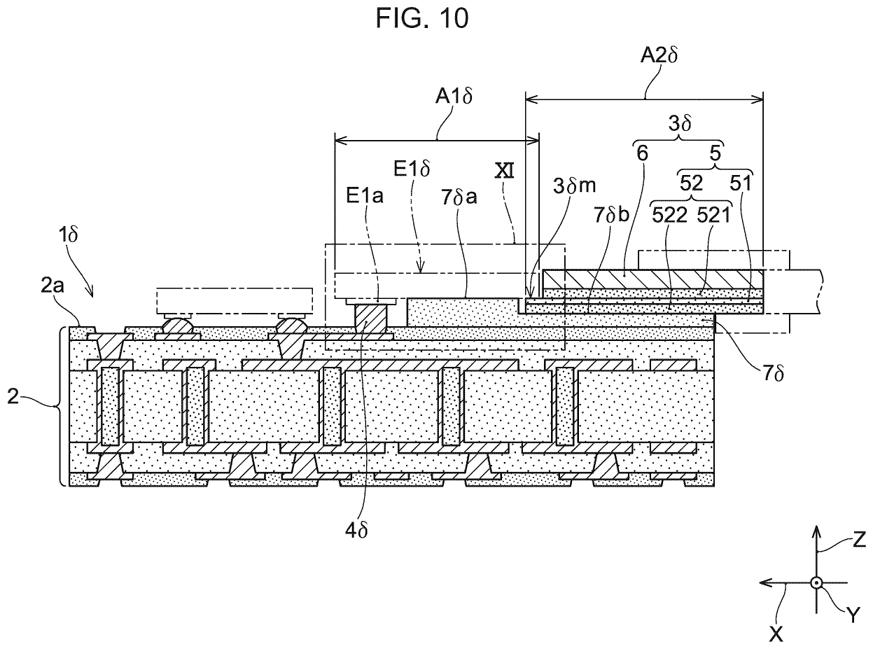

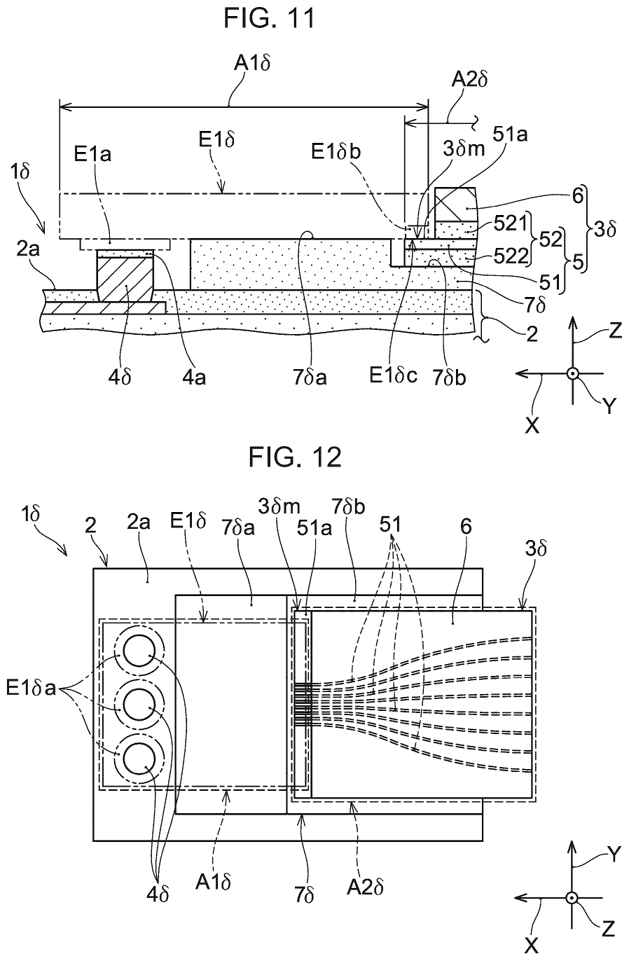

FIGS. 10-12 illustrate a wiring substrate (1δ), which is a modified example of the wiring substrate of the embodiment. FIG. 10 is a cross-sectional view illustrating the wiring substrate (18), which is the modified example of the wiring substrate of the embodiment. FIG. 11 illustrates an enlarged view of a portion (XI) of FIG. 10. FIG. 12 illustrates an example of an optical wiring part (3δ) formed on the wiring substrate (1δ) of FIG. 10 in a plan view.

The wiring substrate (1δ) includes an optical wiring part (3δ) having a structure similar to the optical wiring part 3 included in the wiring substrate 1 of FIGS. 1-3. As illustrated in FIG. 10, the optical wiring part (3δ) differs from the optical wiring part 3 illustrated in FIG. 1 and the like in that an end part (3δm) in the light propagation direction (X direction) in the core part 51 is exposed from the cladding part 52 and the support substrate 6 on the second cladding 522. In the example of FIGS. 10-12, the end part (3δm) of the optical wiring part (38) where the core part 51 is exposed extends in the X direction.

As illustrated in FIG. 11, a light receiving or light emitting part (E1δb) of a component (E1δ) mounted on the wiring substrate (18) has a light receiving or light emitting surface (E1δc) facing laterally and downward relative to the component (E1δ). An upper surface (51a) of the core part 51 exposed from the cladding part 52 and the support substrate 6 is positioned so as to face the light receiving or light emitting surface (E1δc) of the component (E1δ) that is optically coupled to the core part 51. The component (E1δ) is formed such that the light receiving or light emitting part (E1δb) faces the upper surface (51a) of the core part 51 in the Z direction at the end part (3δm) of the optical wiring part (3δ). That is, a component region (A1δ) and an optical wiring region (A2δ) partially overlap in a plan view.

As illustrated in FIG. 11, an upper surface (7δa) of the support member (7δ) in a part of the component region (A1δ) is raised by a thickness of the core part 51 and the second cladding 522 above an upper surface (7δb) of the support member (7δ) in the optical wiring region (A2δ) such that the light receiving or light emitting surface (E1δc) of the component (E1δ) is substantially flush with the upper surface (51a) of the core part 51. Further, a height (dimension in the Z direction) of component (E1δ) connecting parts (4δ) of the electrical wiring part 2 is adjusted such that a lower surface of the component (E1δ) coincides with the upper surface (7δa) of the support member (7δ).

As illustrated in FIGS. 11 and 12, when formed on the wiring substrate (1δ), the component (E1δ) and the optical wiring part (3δ) are formed on the common support member (7δ) on the surface (2a) of the electrical wiring part 2. Therefore, also in this example, similar to the example illustrated in FIGS. 1-3, after the positioning on the wiring substrate (1δ), it is thought that a positional misalignment in the Z direction between the light-receiving or light-emitting part (E1δb) of the component (E1δ) and the core part 51 of the optical wiring part (3δ), both formed on the common support member (7δ), is reduced. Further, it is thought that when the optical wiring part (38) and the component (E1δ) are positioned at positions that allow optical coupling with sufficient efficiency to be achieved, a decrease in optical coupling efficiency between the optical wiring part (3δ) and the component (E1δ) is suppressed during and after the positioning of the optical wiring part (3δ).

For example, when the component (E1δ) is a light receiving element, part of light propagating through the core part 51 toward the end part (3δm) leaks out of the core part 51 from the upper surface (51a) of the core part 51 as evanescent light and enters the light receiving or emitting part (E1δb) as a light receiving part of the component (E1δ). It is thought that, since the upper surface (51a) faces the light receiving or light emitting surface (E1δc) of the component (E1δ) without the cladding part 52 in between, highly efficient optical coupling is achieved.

The wiring substrate of the embodiment is not limited to those having the structures illustrated in the drawings and those having the structures, shapes, and materials exemplified herein. The wiring substrate of the embodiment, particularly the electrical wiring part, may have any layered structure. For example, the electrical wiring part may be a coreless substrate that does not include a core substrate, and may include any number of conductor layers and any number of insulating layers. It is also possible that the conductor pads (11b) are not formed. The wiring substrate may be provided in a state in which a component is already mounted. That is, when a component is mounted, the component is included in the wiring substrate.

Japanese Patent Application Laid-Open Publication No. H05-196844 describes an optical component mounting substrate, on a surface of which an optical wiring is formed. The optical wiring is directly formed on the surface of the substrate. An optical semiconductor element (light emitting element or light receiving element) mounted on the substrate is formed so as to be optically coupled to a core part of a waveguide via a support formed on a surface of the substrate.

In the substrate described in Japanese Patent Application Laid-Open Publication No. H05-196844, it may be possible that it may be possible that the core part of the optical wiring and an optical axis of the optical semiconductor element are not properly aligned in a thickness direction of the substrate. When they are not properly aligned, it is thought that the core part of the waveguide and a light emitting or light receiving part of the optical semiconductor element are not optically coupled with sufficient efficiency. Further, when the substrate is constituted by an organic material, the substrate may expand and contract due to heat generated by the optical semiconductor element or due to heat generated during use or the like. When expansion and contraction occur, in the wiring substrate on which the optical semiconductor element is mounted, it may be possible that the core part of the waveguide and the optical axis of the optical semiconductor element not only become misaligned in the thickness direction of the substrate, but also become misaligned in a direction parallel to the surface of the substrate. As a result, it is thought that such a positional misalignment leads to a decrease in optical coupling efficiency.

A wiring substrate according to an embodiment of the present invention includes: an electrical wiring part that includes an insulating layer and a conductor layer; an optical wiring region that is provided on a surface of the electrical wiring part; and a component region that is provided on the surface of the electrical wiring part and in which a component can be positioned. An optical wiring is formed on the optical wiring region, and a support substrate is formed on the optical wiring.

According to an embodiment of the present invention, it may be possible to suppress a misalignment between the optical wiring of the optical wiring part of the wiring substrate and the optical component that is optically coupled to the optical wiring, thereby improving the coupling efficiency or suppressing a decrease in the coupling efficiency. Further, it may be possible that the mounting of the optical component onto the wiring substrate is facilitated.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
an electrical wiring part comprising an insulating layer and a conductor layer and having an optical wiring region and a component region;
an optical wiring is formed on a surface of the electrical wiring part such that optical wiring is positioned in the optical wiring region of the electrical wiring part; and
a support substrate formed on the optical wiring such that the support substrate is positioned in the optical wiring region of the electrical wiring part on an opposite side with respect to the electrical wiring part,
wherein the component region of the electrical wiring part is configured to position a component on the surface of the electrical wiring part.

2. The wiring substrate according to claim 1, further comprising:
a support member formed between the electrical wiring part and the optical wiring.

3. The wiring substrate according to claim 2, wherein the support member is formed in the optical wiring region.

4. The wiring substrate according to claim 2, wherein the support member is formed on the surface of the electrical wiring part such that the support member is spanning across the optical wiring region and component region of the electrical wiring part.

5. The wiring substrate according to claim 2, wherein the support member is formed on the surface of the electrical wiring part such that the support member is protruding from an end part of the electrical wiring part.

6. The wiring substrate according to claim 1, wherein the optical wiring has an end surface formed flush with an end surface of the support substrate.

7. The wiring substrate according to claim 1, wherein the electrical wiring part is formed such that the optical wiring region and the component region are spaced apart from each other.

8. The wiring substrate according to claim 1, wherein the electrical wiring part is formed such that the optical wiring region and the component region are partially overlapping with the support member.

9. The wiring substrate according to claim 2, wherein the electrical wiring part has a connecting part configured to connect the component such that the component is optically coupled to the optical wiring.

10. The wiring substrate according to claim 9, wherein the connecting part is formed on the surface of the electrical wiring part adjacent to the support member.

11. The wiring substrate according to claim 10, wherein the electrical wiring part includes a conductive connecting member formed on the connecting part such that the conductive connective member is configured to connect the connecting part to the component.

12. The wiring substrate according to claim 2, wherein the optical wiring has an end surface formed flush with an end surface of the support substrate.

13. The wiring substrate according to claim 2, wherein the electrical wiring part is formed such that the optical wiring region and the component region are spaced apart from each other.

14. The wiring substrate according to claim 2, wherein the electrical wiring part is formed such that the optical wiring region and the component region are partially overlapping with the support member.

15. The wiring substrate according to claim 1, wherein the electrical wiring part has a connecting part configured to connect the component such that the component is optically coupled to the optical wiring.

16. The wiring substrate according to claim 15, wherein the connecting part is formed on the surface of the electrical wiring part adjacent to the support member.

17. The wiring substrate according to claim 16, wherein the electrical wiring part includes a conductive connecting member formed on the connecting part such that the conductive connective member is configured to connect the connecting part to the component.

18. The wiring substrate according to claim 3, wherein the optical wiring has an end surface formed flush with an end surface of the support substrate.

19. The wiring substrate according to claim 3, wherein the electrical wiring part is formed such that the optical wiring region and the component region are spaced apart from each other.

20. The wiring substrate according to claim 3, wherein the electrical wiring part is formed such that the optical wiring region and the component region are partially overlapping with the support member.
